(19) United States
(12) Patent Application Publication
(10) Pub. No.: US 2007/0037374 A1
(43) Pub. Date: Feb. 15, 2007

(54) Semiconductor device and its manufacturing method

(75) Inventors: Yumi Hayashi, Ayase-shi (JP); Hideki Shibata, Yokohama-shi (JP)

Correspondence Address: FOLEY AND LARDNER LLP;SUITE 500, 3000 K STREET NW, WASHINGTON, DC, 20007, US

(73) Assignee: KABUSHIKI KAISHA TOSHIBA

(21) Appl. No.: 11/280,812

(22) Filed: Nov. 17, 2005

(30) Foreign Application Priority Data
Aug. 15, 2005 (JP) 2005-235318

(51) Int. Cl. H01L 21/44

(52) U.S. Cl. 438/597

(57) ABSTRACT

A semiconductor device comprising a wiring suitable for miniaturization and manufacturing method thereof are disclosed. According to one aspect of the present invention, it is provided a semiconductor device comprising an insulator formed above a semiconductor substrate, and a wiring formed in the insulator and having surface roughness capable of suppressing surface scattering of electrons and reduction in electrical conductivity thereof.

### CROSS-REFERENCE TO RELATED APPLICATIONS

This application is based upon and claims the benefit of priority from prior Japanese Patent Application No. 2005-235318, filed Aug. 15, 2005, the entire contents of which are incorporated herein by reference.

### BACKGROUND OF THE INVENTION

1. Field of the Invention

The present invention relates to a semiconductor device and its manufacturing method, and more particularly to a semiconductor device which comprises a wiring suitable for miniaturization, and its manufacturing method.

2. Description of the Related Art

With progress of miniaturization of semiconductor devices to achieve higher integration, higher speed operation and higher performance thereof, an increase in wiring resistance owing to miniaturization of a wiring is one of the problems.

In a miniaturized semiconductor device, wiring performance is not only affected by properties of a wiring material, feature size, patterning variation and the like but also dependent on surface roughness of the wiring. To improve wiring performance, technologies of reducing surface roughness of a wiring metal or a barrier metal are disclosed, for example, in US Patent No. 6200894 B1 and U.S. patent application Ser. No. 08/825216.

U.S. Pat. No. 6,200,894 B1 discloses a technology of improving electro-migration resistance in an aluminum wiring and a contact plug. According to this technology, by smoothing an underlying insulator, surface of the aluminum film formed thereon is smoothed, and also a film structure, i.e., orientation of crystal grains, is improved, thereby increasing electro-migration resistance of the aluminum film.

U.S. patent application Ser. No. 08/825216 discloses a technology of forming a titanium nitride film as a barrier metal with a lower resistivity and smaller surface roughness by controlling deposition conditions of a titanium nitride film.

In the above technologies, problems caused by a reduced wiring size are not taken into consideration. J. J. Thomson points out in his theory that, in a miniaturized semiconductor device, when a wiring width and/or a wiring thickness are close to a mean free path of electrons in the wiring metal, surface roughness of the wiring affects electrical conductivity of the metal wiring (e.g., see pp. 52 to 54 of “Physical Properties of Thin Metal Film”, by G. P. Zhigal'skii, B. K. Jones, issued by Taylor & Francis). FIG. 1 shows a relation between a wiring width and electrical conductivity of a copper (Cu) wiring calculated based on Thomson's theory. In the drawing, a horizontal axis indicates a wiring width, and a vertical axis indicates relative electrical conductivity. Here, the relative electrical conductivity (σ_{f}/σ₀) is a ratio of electrical conductivity (σ_{f}) in a narrow metal to electrical conductivity (σ0) in a metal having an infinite size (referred to as bulk metal). A mean free path of electrons in Cu at room temperature is known as about 40 nm. It is shown that when the wiring width becomes narrower and approaches 40 nm, electrical conductivity reduces rapidly. The reduction in electrical conductivity means an increase in resistance. Such a reduction in electrical conductivity is caused by scattering of electrons due to rough surface of the wiring and reducing in effective mean free path of electrons thereby. By the miniaturization of the semiconductor device, the wiring width has been approached 40 nm of a mean free path of electrons in Cu.

### BRIEF SUMMARY OF THE INVENTION

According to one aspect of the present invention, it is provided a semiconductor device comprising: an insulator formed above a semiconductor substrate; and a wiring formed in the insulator and having surface roughness capable of suppressing surface scattering of electrons and reduction in electrical conductivity thereof.

According to another aspect of the present invention, it is provided a method for manufacturing a semiconductor device, comprising: forming an insulator above a semiconductor substrate; forming at least one of a wiring groove and a contact hole in the insulator; forming a barrier metal in at least one of the wiring groove and the contact hole; smoothing a surface of at least one of the wiring groove, the contact hole and the barrier metal; and forming a copper wiring on the barrier metal.

### BRIEF DESCRIPTION OF THE SEVERAL VIEWS OF THE DRAWING

FIG. 1 shows a relation between a wiring width and electrical conductivity of a copper wiring calculated based on Thomson's theory;

FIG. 2 is a diagram showing a calculation model based on Thomson's theory used in an embodiment according to the present invention;

FIG. 3 is a diagram showing a calculation model of a wiring having surface roughness according to an embodiment of the present invention;

FIG. 4 is a diagram showing an influence of surface roughness on normalized electrical conductivity of a Cu wiring calculated according to the embodiment of the present invention;

FIG. 5 is a diagram showing an influence of surface roughness on relative electrical conductivity of the Cu wiring normalized by electrical conductivity of a thin film Cu wiring having a smooth surface and the same thickness calculated according to the embodiment of the present invention;

FIG. 6 is a diagram showing an influence of surface roughness on the electrical conductivity of the Cu wiring having different wiring widths calculated according to the embodiment of the present invention;

FIG. 7 is a diagram showing a relation between an allowable surface roughness and a wiring width of the Cu wiring calculated according to the embodiment of the present invention;

FIG. 8 is a sectional view of a semiconductor device shown to explain a Cu multilevel wiring used in embodiments of the present invention;

FIGS. 9A, 9B are enlarged sectional views of a barrier metal surface to explain a first embodiment of the present invention;

FIGS. 10A to 10C are sectional views of a wiring structure to explain a second embodiment of the present invention;

FIG. 11 is a sectional view of an interlevel insulator to explain a third embodiment of the present invention;

FIG. 12A is a plan view of a resist pattern shown to explain a fourth embodiment of the present invention;

FIG. 12B is a sectional view of the resist pattern according to the fourth embodiment;

FIGS. 13A, 13B are plan views of resist patterns shown to explain a fifth embodiment of the present invention; and

FIG. 14 is a sectional view of a stacked film for etching shown to explain a sixth embodiment of the present invention.

### DETAILED DESCRIPTION OF THE INVENTION

The embodiments of the present invention will be described with reference to the accompanying drawings. Throughout the drawings, corresponding portions are denoted by corresponding reference numerals. Each of the following embodiments is illustrated as one example, and therefore the present invention can be variously modified and implemented without departing from the spirits of the present invention.

The present invention is directed to a miniaturized semiconductor device which comprises a wiring having predetermined surface roughness.

As miniaturizing the wiring, e.g., a wiring width becomes 100 nm or less, electrons moving in the wiring are scattered by rough surface of the wiring to cause a reduction in electrical conductivity, that is, an increase in wiring resistance. Thus, it is important to control the surface roughness of the wiring to be small, thereby suppressing the increase in wiring resistance.

A critical surface roughness of the wiring can be determined by extending Thomson's theory. Thomson's theory argues about effects of metal surface roughness on electrical conductivity in a narrow metal when a width (or thickness) of the metal is equal to or less than a mean free path of electrons in the metal. Strictly, Thomson's theory is applied to a case in which the metal width is equal to or less than the mean free path of electrons as described above. However, the theory can be applied to a metal width of approximately severalfold.

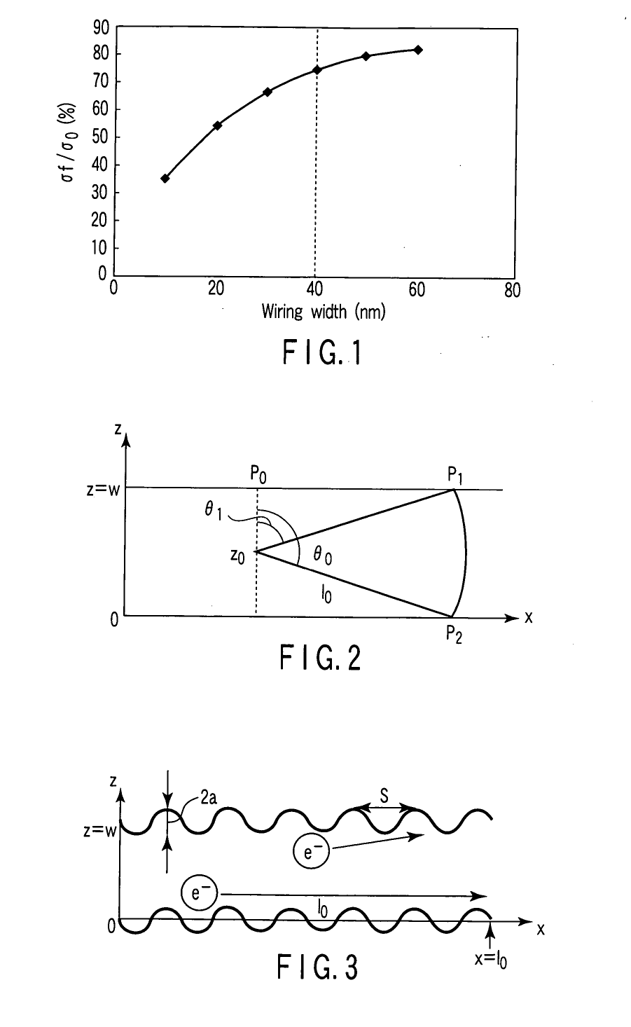

First, based on Thomson's theory, it is calculated that an effective mean free path l̅_{eff} of electrons in a thin film wiring smaller in width (or thickness) than a mean free path l₀ of electrons in a metal. FIG. 2 shows a calculation model used in one embodiment of the present invention, in which an electron at a position z₀ in a wiring with a width w will be considered. An intersection point between a line drawn from the point z₀ in parallel to a z axis and an upper surface of the wiring is set as P₀. A circle whose radius is equal to the mean free path l₀ of electrons is drawn centered from the point z₀ in a positive direction of an x axis, and intersection points with the upper and lower surfaces of the wiring are set as P₁ and P2, respectively. An angle from the point P₀ to the point P₁ intersecting the upper surface (i.e., an angle P₀-z₀-P₁) is set as θ₁, and an angle to the point P₂ intersecting the lower surface (i.e., an angle P₀-z₀-P₂) is set as 00. In this case, if an angle θ from the z axis is smaller than θ₁ or larger than θ₀, the electron is scattered by the surface of the wiring. Thus, the effective mean free path l̅_{eff} of the electron becomes smaller than the original mean free path l₀. According to Thomson's theory, the effective mean free path l̅_{eff} of electrons in the thin film metal is given by the following equation:

$${\overline{l}}_{eff} = \frac{1}{w} {\int }_{0}^{w} ⅆ z {\int }_{0}^{π} {l}_{f} sin θ ⅆ θ \qquad Eq . ( 1 )$$

where, l_{f} is a mean free path of electrons in the thin film wiring having a smooth surface, which is obtained by the following equation (2) with respect to a size of θ:

$${l}_{f} = \{ \begin{matrix}\frac{w - {z}_{0}}{cos θ} & 0 \leq θ \leq {θ}_{l} \\ {l}_{o} & {θ}_{l} \leq θ \leq {θ}_{0} \\ - \frac{{z}_{0}}{cos θ} & {θ}_{0} \leq θ \leq π\end{matrix} \qquad Eq . ( 2 )$$

In a thin film metal, a mean free path l̅_{f} of electrons can be represented by using an electrical conductivity σ₀ in a bulk metal and electrical conductivity σ_{f} in the thin film metal. As electrical conductivity σ is proportional to the mean free path l of electrons, their relation is given as follows:
σ_{f}/σ₀= l̅_{f}/ l̅₀ Eq. (3)
The left side of the equation (3) is normalized electrical conductivity σ_{f}/σ₀. Accordingly, by substituting the equation (3) with the equation (1) to calculate, the normalized electrical conductivity σ_{f}/σ₀ is obtained by the following equation:

$$\frac{{σ}_{f}}{{σ}_{0}} = \frac{1}{2} \frac{w}{{l}_{0}} [ ln ( \frac{{l}_{0}}{w} ) + \frac{3}{2} ] \qquad Eq . ( 4 )$$

It can be understood from the equation (4) that if the wiring width w becomes equal to the mean free path l₀ of electrons in the bulk metal, effective electrical conductivity σ_{f} becomes 75% of the electrical conductivity σ₀ of electrons in the bulk metal.

The above discussion is in the case of the wiring with a smooth surface. However, an actual surface of a metal wiring has certain amount of roughness. Surface roughness of the metal wiring or the like can be measured by, e.g., an atomic force microscope (AFM) with an accuracy of order of 0.1 nm. It is said that actual surface roughness of the metal wiring, e.g., a Cu wiring, is at least about 10 nm. Thus, to consider an influence of electron scattering caused by the surface roughness of the wiring, Thomson's theory can be developed as follows.

An actual surface morphology of the metal wiring is not uniform but complex shape. To simplify the description, however, the surface morphology of the wiring is modeled as shown in FIG. 3. The surface is assumed to be formed into a sine wave shape having amplitude (maximum width) of 2a and a period of s. In this case, front side and backside surface shape z₁ and z₂ are given by the following equation:

$$\{ \begin{matrix}{z}_{1} = w + a sin ( \frac{2 π x}{s} ) \\ {z}_{2} = a sin ( \frac{2 π x}{s} )\end{matrix} \qquad Eq . ( 5 )$$

An effective mean free path l̅_{fR} of electrons in the thin film wiring having the above surface roughness is obtained by the following equation (6) which is a modification of the equation (1):

$${\overline{l}}_{fR} = \frac{1}{w} {\int }_{0}^{{l}_{0}} ⅆ x {\int }_{a sin ( \frac{2 π x}{s} )}^{w + a sin ( \frac{2 π x}{s} )} ⅆ z {\int }_{0}^{π} {l}_{f} sin θ ⅆ θ \qquad Eq . ( 6 )$$

Solving the equation (6), its solution is represented by the following equation:

$${\overline{l}}_{fR} = \frac{1}{2 {wl}_{0}} {\int }_{0}^{{l}_{0}} \frac{{( a sin ( \frac{2 π x}{s} ) )}^{2}}{2} ln \vert a sin x \vert - \frac{{( w - a sin ( \frac{2 π x}{s} ) )}^{2}}{2} ln \vert w - a sin ( \frac{2 π x}{s} ) \vert + ( \frac{1}{2} + ln {l}_{0} ) \{ {w}^{2} - \frac{1}{2} ( 2 aw sin ( \frac{2 π x}{s} ) + {w}^{2} ) \} + {w}^{2} - \frac{{( w + a sin ( \frac{2 π x}{s} ) )}^{2}}{2} ln \vert w + a sin ( \frac{2 π x}{s} ) \vert + \frac{{( a sin ( \frac{2 π x}{s} ) )}^{2}}{2} ln \vert a sin ( \frac{2 π x}{s} ) \vert + ( \frac{1}{4} + \frac{1}{2} ln {l}_{0} ) ( 2 aw sin ( \frac{2 π x}{s} ) + {w}^{2} ) ⅆ x \qquad Eq . ( 7 )$$

As in the case of the equation (3), electrical conductivity in the bulk metal is set as σ₀ and electrical conductivity in the thin film metal having roughness is set as σ_{fR}. As the electrical conductivity is proportional to the mean free path of electrons, the equation (3) can be modified to the following equation:
σ_{fR}/σ₀= l̅_{fR}/l₀ Eq.(8)
Accordingly, the electrical conductivity σ_{fR}/σ₀ normalized by using the electrical conductivity σ₀ in the bulk metal is represented by the following equation (9) using the equation (7):

$$\frac{{σ}_{fR}}{{σ}_{0}} = \frac{{\overline{l}}_{fR}}{{l}_{0}} = \frac{1}{2 w} {\int }_{0}^{{l}_{0}} \frac{{( a sin ( \frac{2 π x}{s} ) )}^{2}}{2} ln \vert a sin x \vert - \frac{{( w - a sin ( \frac{2 π x}{s} ) )}^{2}}{2} ln \vert w - a sin ( \frac{2 π x}{s} ) \vert + ( \frac{1}{2} + ln {l}_{0} ) \{ {w}^{2} - \frac{1}{2} ( 2 aw sin ( \frac{2 π x}{s} ) + {w}^{2} ) \} + {w}^{2} - \frac{{( w + a sin ( \frac{2 π x}{s} ) )}^{2}}{2} ln \vert w + a sin ( \frac{2 π x}{s} ) \vert + \frac{{( a sin ( \frac{2 π x}{s} ) )}^{2}}{2} ln \vert a sin ( \frac{2 π x}{s} ) \vert + ( \frac{1}{4} + \frac{1}{2} ln {l}_{0} ) ( 2 aw sin ( \frac{2 π x}{s} ) + {w}^{2} ) ⅆ x \qquad Eq . ( 9 )$$

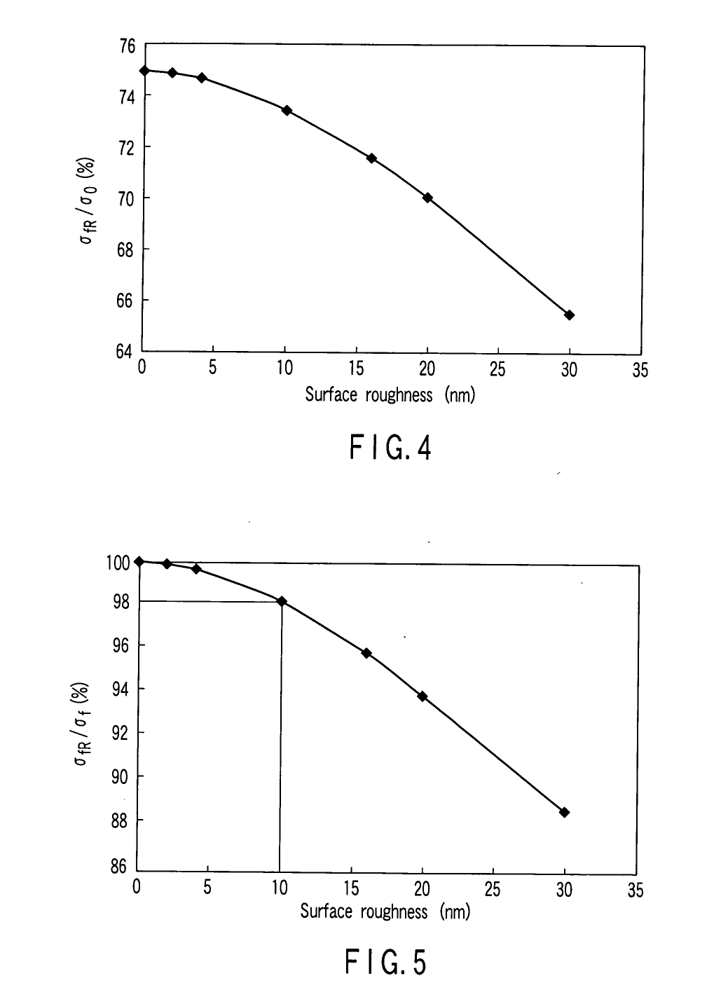

FIG. 4 shows a result of an influence to a normalized electrical conductivity σ_{fR}/σ₀ as a function of the surface roughness by applying the equation (9) to a Cu wiring with a wiring width w=40 nm. In this case, a mean free path of electrons in Cu is set to 10=40 nm and a period of surface roughness is presumed as s=2 π (rad). It can be understood from FIG. 4 that the electrical conductivity in the thin film is reduced to 75% of that in the bulk metal even when the surface is smooth. It can be additionally understood that the electrical conductivity is exponentially reduced as the surface roughness becomes larger. In the case of FIG. 4, the reduction in electrical conductivity becomes conspicuous when the surface roughness reaches about 10 nm or more, in other words, when the surface roughness exceeds 25% of the mean free path of electrons.

As the semiconductor device is miniaturized further, it is required to suppress an increase in resistance of a multilevel wiring. It is known that a resistance value of the wiring of the semiconductor device varies due to various factors. For example, the factors include a variation in patterning size of the wiring, a variation in film thickness of the wiring, a variation in resistivity of the wiring material itself, and the like. Smaller variations are preferable. To suppress a resistance variation of the overall semiconductor device to 10% or less, an increase in resistivity of the wiring metal itself, i.e., a reduction in electrical conductivity, must be controlled to, e.g., 2% or less from the standpoint of designing the semiconductor device.

As means therefor, the surface of the wiring may be smoothed to reduce surface roughness which causes a reduction in electrical conductivity. Thus, when the equation (9) is modified and normalized by using electrical conductivity σ_{f} of a wiring with the same wiring width w having a smooth surface in place of the electrical conductivity of the bulk metal σ₀, it is represented by the following equation:

$$\frac{{σ}_{fR}}{{σ}_{f}} = \frac{{\overline{l}}_{fR}}{{\overline{l}}_{f}} = \frac{{l}_{0}}{2 w {\overline{l}}_{f}} {\int }_{0}^{{l}_{0}} \frac{{( a sin ( \frac{2 π x}{s} ) )}^{2}}{2} ln \vert a sin x \vert - \frac{{( w - a sin ( \frac{2 π x}{s} ) )}^{2}}{2} ln \vert w - a sin ( \frac{2 π x}{s} ) \vert + ( \frac{1}{2} + ln {l}_{0} ) \{ {w}^{2} - \frac{1}{2} ( 2 aw sin ( \frac{2 π x}{s} ) + {w}^{2} ) \} + {w}^{2} - \frac{{( w + a sin ( \frac{2 π x}{s} ) )}^{2}}{2} ln \vert w + a sin ( \frac{2 π x}{s} ) \vert + \frac{{( a sin ( \frac{2 π x}{s} ) )}^{2}}{2} ln \vert a sin ( \frac{2 π x}{s} ) \vert + ( \frac{1}{4} + \frac{1}{2} ln {l}_{0} ) ( 2 aw sin ( \frac{2 π x}{s} ) + {w}^{2} ) dx \qquad Eq . ( 10 )$$

FIG. 5 shows a result of a calculation on an influence of surface roughness on relative electrical conductivity σ_{fR}/σ_{f} normalized by electrical conductivity σ_{f} of a thin film metal with a smooth surface and the same thickness by applying the equation (10) to a Cu wiring with a wiring width=40 nm, as in the case of FIG. 4. To suppress an increase in resistivity of the wiring, i.e., a reduction in electrical conductivity, to 2% or less in the miniaturized Cu wiring, it can be understood from FIG. 5 that surface roughness must be controlled to 10 nm or less in the case of the wiring with 40 nm wide.

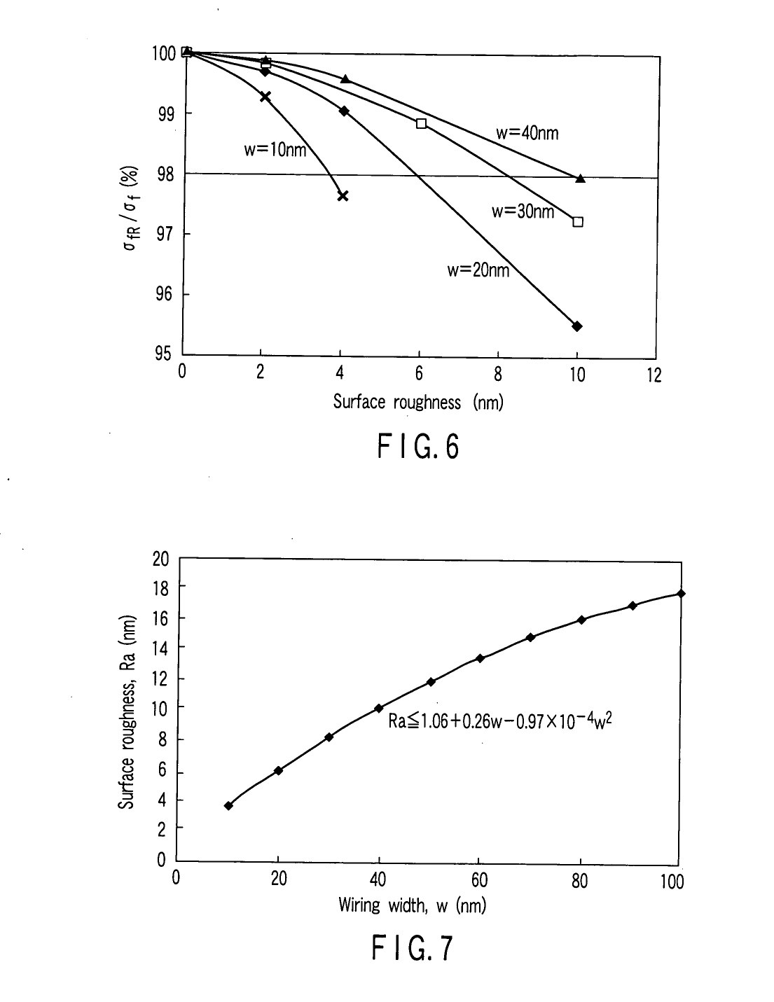

FIG. 6 similarly shows a result of calculating an influence of surface roughness on relative electrical conductivity σ_{fR}/σ_{f} of a wiring in the case of a Cu wiring with a wiring width of 10 nm to 40 nm. It can be understood from FIG. 6 that to suppress a reduction in relative electrical conductivity to 2% or less, for example, allowable surface roughness Ra is about 3.6 nm or less in the Cu wiring with 10 nm wide. Similarly, allowable surface roughness Ra is 5.9 nm or less in a wiring width of 20 nm, and 8.3 nm or less in a wiring width of 30 nm.

FIG. 7 shows a relation between allowable surface roughness Ra and a wiring width w calculated to each of Cu wirings with wiring width of 10 nm to 100 nm, as described above. A line interconnecting points in FIG. 7 is calculated by a least square method, for the Cu wiring with a wiring width of 100 nm or less, the allowable surface roughness is obtained as a function of the wiring width w by the following equation:
Ra≦1.06+0.26 w−0.97×10⁻⁴ w² Eq. (11).

For simplicity, the above calculation has been described by considering the surface having fixed roughness repeatedly. In the actual wiring, however, the surface is constituted of a complex roughness, in which roughness with various amplitude and periods are mixed, and the roughness in which amplitude and periods thereof are larger and/or smaller than that of the model is arranged at random. Thus, the surface roughness calculated above can be rephrased to correspond to mean surface roughness Ra in the actual wiring.

As apparent from the aforementioned discussion, even when the patterning size of the wiring changes, by controlling the mean surface roughness Ra of the Cu wiring to be within a range satisfying the equation (11) with respect to the wiring width w, it can be suppressed a reduction in electrical conductivity of the Cu wiring to 2% or less.

Thus, in the miniaturized semiconductor device, the surface roughness Ra of the wiring can be quantitatively determined with respect to the designed wiring width w, thereby a wiring having surface roughness based on a result thereof can be designed and manufactured.

Next, a semiconductor device in which surface roughness of a wiring is controlled, i.e., smoothed, to meet the equation (11) and its manufacturing method will be described by way of some embodiments. However, the semiconductor device and its manufacturing method are not limited to the embodiments.

To make a surface of the wiring, especially Cu wiring, smooth, various methods are available, e.g., a method of smoothing a surface of an underlying layer, such as an interlevel insulator or a barrier metal, formed the wiring thereon, smoothing a resist for patterning or an etching mask, and the like. The embodiments of smoothing the wiring surface will be described below by taking Cu wiring as an example.

### First Embodiment

A first embodiment of the present invention is directed to a semiconductor device which comprises a wiring with small surface roughness formed on a smoothed barrier metal as an underlying layer for a Cu wiring, and its manufacturing method.

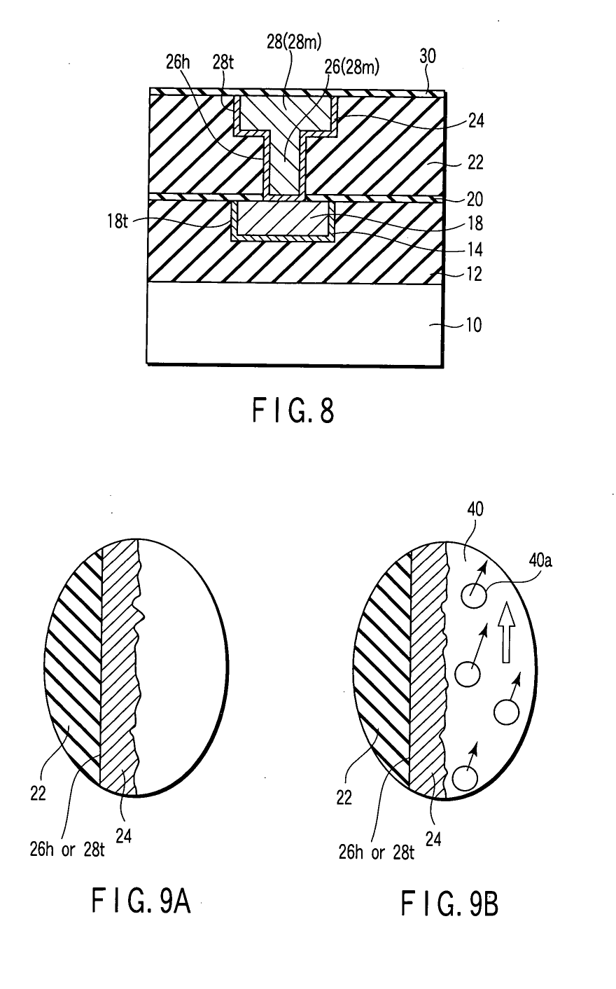

FIG. 8 is a sectional view of the semiconductor device to explain a Cu multilevel wiring. To simplify the description, Cu wirings 18, 28 of two layers are shown. According to the embodiment, a first interlevel insulator 12 is formed over an active element (not shown) such as a metal oxide semiconductor field effect transistor (MOSFET) formed on a semiconductor substrate 10 , e.g., a silicon substrate, and planarized its surface by, e.g., chemical mechanical polishing (CMP). A first wiring groove 18t is formed in the first interlevel insulator 12, and the first wiring 18 is formed therein via a first barrier metal 14 . A first diffusion preventive film 20 is formed on an entire surface of the first wiring 18 and the first interlevel insulator 12. A second interlevel insulator 22 is formed on the first diffusion preventive film 20. In the second interlevel insulator 22, a contact hole 26h to be connected a second wiring 28 to the first wiring 18 and a second wiring groove 28t are formed. In the contact hole 26h and the second wiring groove 28t, a contact plug 26 and the second wiring 28 are formed via a second barrier metal 24. A second diffusion preventive film 30 is formed on an entire surface of the second wiring 28 and the second interlevel insulator 24 to complete a structure shown in FIG. 8.

The interlevel insulators 12, 22 are preferably low dielectric constant insulators. For example, an organic silicon film such as a methyl siloxane film containing siloxane such as SiOC or SiOCH, an organic film such as polyallylene ether, or a porous film thereof can be used. The barrier metals 14, 24 are conductive films to prevent wiring material from diffusing out. For example, tantalum (Ta), tantalum nitride (TaN), or titanium nitride (TiN) can be used. For the diffusion preventive films 20, 30, an insulator capable of preventing Cu diffusion, e.g., a silicon nitride film (SiN film), can be used.

The Cu wiring 28 can be formed by a so-called single or dual damascene to deposit Cu 28m in the wiring groove 28t and/or the contact hole 26h formed in the interlevel insulator 22 by, e.g., electro-plating. When the Cu 28m is deposited by the electro-plating, the Cu 28m is deposited not only in the wiring groove 28t and the contact hole 26h but also on the surface of the interlevel insulator 22. Therfore, after the deposition of the Cu 28m, the Cu 28m deposited other than in the wiring groove 28t is removed by, e.g., CMP. For example, this CMP is executed in two steps. At the first step, the thickly deposited Cu 28m is removed by using the barrier metal 24 deposited on the surface of the interlevel insulator 22 as a stopper. Subsequently, the barrier metal 24 and the Cu 28m on the interlevel insulator 22 are removed by a method called barrier CMP to complete the wiring 28.

FIGS. 9A and 9B are enlarged sectional views of the surface of the contact hole 26h and/or the wiring groove 28t to explain the embodiment. Referring to FIG. 9A, a surface of the barrier metal 24 formed on a surface of the contact hole 26h or the wiring groove 28t is not always smooth. Surface roughness of each of the Cu wiring 28 and the contact plug 26 deposited on the surface of the underlying barrier metal 24 having such large surface roughness inevitably becomes large.

Thus, as shown in FIG. 9B, before Cu is deposited, a liquid capable of polishing, e.g., CMP slurry 40, is supplied and circulated in the wiring groove 28t and the contact hole 26h to smooth the surface of the barrier metal 24. As the CMP slurry 40 contains polishing abrasives 40a and an etchant, convex parts constituting the roughness of the underlying layer can be selectively polished and removed. For the smoothing of the barrier metal 24, a slurry having high polishing efficiency to the barrier metal, e.g., the slurry for the barrier CMP described above, is preferable. By depositing Cu on a smoothed surface of the barrier metal 24, it can be formed a Cu wiring 28 whose mean surface roughness is controlled to be small.

Thus, in the wiring with a wiring width of 100 nm or less, the mean surface roughness of the wiring can be controlled within a range defined by the equation (11) with respect to the wiring width. Thus, it is provided a semiconductor device capable of suppressing a reduction in electrical conductivity caused by surface roughness of a wiring to 2% or less, and its manufacturing method.

Accordingly, in the miniaturized semiconductor device, it is provided a semiconductor device, which can be determined surface roughness of a wiring quantitatively and comprises a wiring having surface roughness designed based on a result thereof, and its manufacturing method.

### Second Embodiment

A second embodiment of the present invention is directed to a semiconductor device which comprises a wiring with small surface roughness formed on a smoothed surface of a low dielectric constant insulator used as an interlevel insulator, and its manufacturing method.

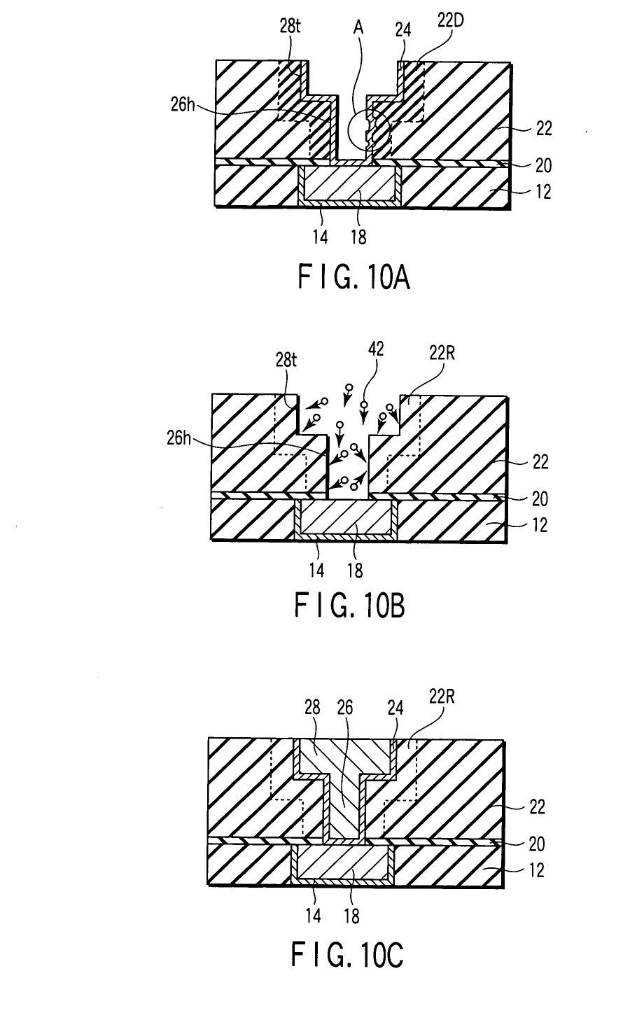

When a feature size of a semiconductor device is reduced to, for example, 100 nm or less, a low dielectric constant insulator with a specific dielectric constant of 3.0 or less, or more preferably 2.5 or less, is desired as an interlevel insulator to reduce parasitic capacitance of a wiring. FIGS. 10A to 10C are sectional views of a wiring structure to explain the embodiment. As shown in FIG. 10A, such a low dielectric constant insulator 22 is generally a porous organic silicon film or organic film. When a wiring groove 28t or a contact hole 26h is patterned in the porous low dielectric constant insulator 22 by, e.g., anisotropic etching, in the vicinity of the patterned surface of the low dielectric constant insulator 22, for example, carbon is released from the insulator to form processing damage or a process damaged layer 22D. As the process damaged layer 22D is low in mechanical strength, surface roughness may be enlarged by the processing damage, like a portion surrounded by a circle A in FIG. 10A, or a part of a barrier metal is oxidized by moisture or the like released from the process damaged layer 22D to increase surface roughness.

Therefore, as shown in FIG. 10B, before a barrier metal 24 is formed, damage repair agent 42 is supplied to the damaged layer in, e.g., liquid or gas phase, and then heated to cause reaction to supply carbon to the process damaged layer 22D in the near surface of the low dielectric constant insulator. Specifically, the etched surface is heated in an atmosphere containing the damage repair agent 42, e.g., hexamethyl-di-silazane (HMDS), at a temperature of 150° C. to 350° C. Accordingly, a carbon concentration and/or a film density in the surface of the process damaged layer 22D is recovered equal to or more than those in the bulk, thereby a recovered layer 22R can be formed.

As shown in FIG. 10C, Cu is deposited via the barrier metal 24 on the recovered layer 22R of the low dielectric constant insulator (interlevel insulator) 22 in which damage is recovered and the surface is smoothed. Accordingly, it can be formed a contact plug 26 and a Cu wiring 28 whose mean surface roughness is controlled to be small.

Thus, in the wiring with a wiring width of 100 nm or less, the mean surface roughness of the wiring can be controlled within a range defined by the equation (11) with respect to the wiring width, as in the case of the first embodiment. Accordingly, it is provided a semiconductor device capable of suppressing a reduction in electrical conductivity caused by surface roughness of the wiring to 2% or less, and its manufacturing method.

### Third Embodiment

A third embodiment of the present invention is directed to a semiconductor device which comprises a Cu wiring with small surface roughness formed on a smoothed surface by sealing pores 23 on surfaces of a wiring groove 28t and a contact hole 26h formed in a porous low dielectric constant insulator as an interlevel insulator 22, and its manufacturing method.

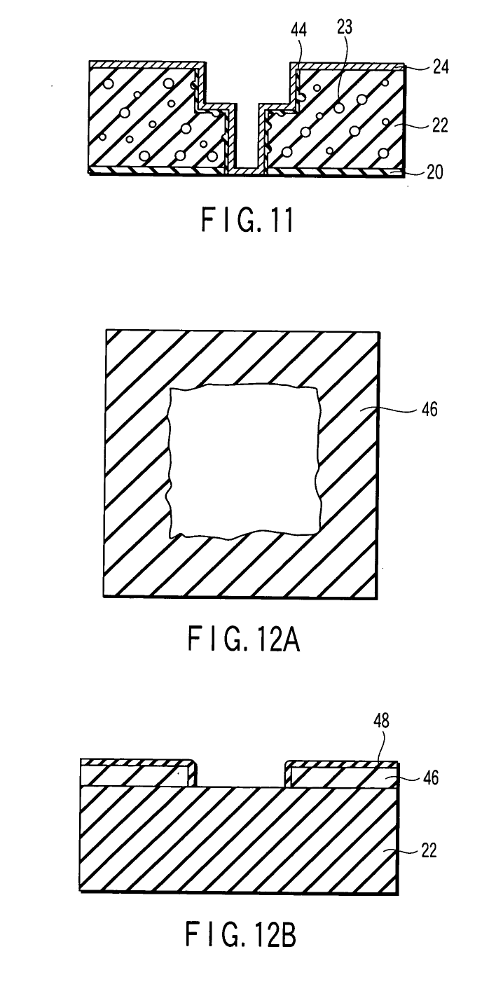

FIG. 11 is a sectional view of an interlevel insulator to explain the embodiment. The pore 23 in a patterned surface of the porous interlevel insulator 22 can be sealed by using a coating film 44 of, e.g., SiC, SiOC, SiCN or the like. When a barrier metal 24 is deposited on the surface of the porous interlevel insulator 22, the barrier metal 24 may not be deposited well on the pore 23 portions. However, when a film such as the coating film 44 is deposited on the surface of the interlevel insulator 22 by, e.g., chemical vapor deposition (CVD), plasma-enhanced CVD (PECVD), or atomic layer deposition (ALD), the pore 23 on the surface can be sealed. By depositing the barrier metal 24 on such a smoothed surface by sealing the pore 23 in the etched surface of the interlevel insulator 22 as described above, the barrier metal 24 can be uniformly deposited, and its surface can be smoothed, as shown in FIG. 11B.

By depositing Cu on the smoothed surface of the barrier metal 24, it can be formed a Cu wiring (not shown) having small mean surface roughness.

Thus, in a wiring with a wiring width of 100 nm or less, the mean surface roughness of the wiring can be controlled within a range defined by the equation (11). with respect to the wiring width. Accordingly, it can be provided a semiconductor device capable of suppressing a reduction in electrical conductivity caused by surface roughness of a wiring to 2% or less, and its manufacturing method.

### Fourth Embodiment

A fourth embodiment of the present invention is directed to a semiconductor device which comprises a Cu wiring with a small surface roughness formed in a smoothed wiring groove and contact hole in an interlevel insulator 22 patterned by using a resist pattern having smoothed surface as a mask, and its manufacturing method.

A pattern of a resist 46 patterned by lithography may comprise a rough edge surface, for example, as shown in FIG. 12A. If the interlevel insulator 22 is etched by using such a resist 46 with rough edge as a mask to form a wiring groove and/or a contact hole, roughness of the resist 46 is transferred to a patterned surface of the interlevel insulator 22 to form a wiring groove and/or a contact hole having a rough surface.

Therefore, as shown in a sectional view of FIG. 12B, after forming a pattern of a wiring groove in the resist 46, for example, a smoothing film 48 such as a water-soluble organic film or a water-soluble polymer film is formed on the resist pattern by, e.g., a coating method. This smoothing film 48 is formed only on the resist 46. The rough pattern edge surface of the resist 46 is covered with the smoothing film 48 and thus smoothed. For the smoothing film 48, for example, a water-soluble organic film or a water-soluble polymer film used in a process of resolution enhancement lithography assisted by chemical shrink (RELACS) can be used.

The interlevel insulator 22 is etched by using the resist 46 with the smoothed pattern as a mask, whereby a wiring groove and a contact hole having smoothed surfaces can be formed. By depositing a barrier metal and Cu in the wiring groove and the contact hole having smoothed surface, it can be formed a Cu wiring with small mean surface roughness.

Thus, in the wiring with a wiring width of 100 nm or less, the mean surface roughness of the wiring can be controlled within a range defined by the equation (11) with respect to the wiring width. Accordingly, it can be provided a semiconductor device capable of suppressing a reduction in electrical conductivity caused by surface roughness of a wiring to 2% or less, and its manufacturing method.

### Fifth Embodiment

A fifth embodiment of the present invention is directed to a semiconductor device which comprises a Cu wiring with small surface roughness formed in a wiring groove 28t and a contact hole 26h having smooth surfaces formed in an interlevel insulator 22 by smoothing an edge of a resist pattern by multiple exposures, and its manufacturing method.

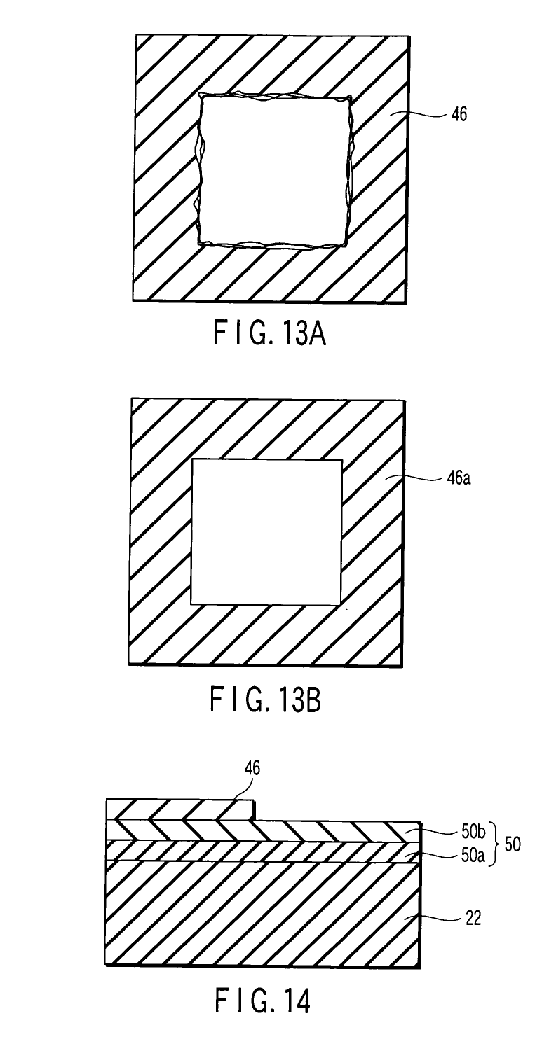

When the resist pattern is formed by only one exposure, roughness may occur in an edge surface of a resist 46, for example, as shown in the plane view of FIG. 12A. Therefore, exposure to the resist is repeated by a plurality of times. Although current exposure device is controlled by a computer to exhibit good reproducibility, even when multiple exposures are carried out at the same position, for each exposure, an exposure position may slightly be change in nm order and an amount of defocusing may also slightly be varied. Thus, as shown in a plane view of FIG. 13A, exposure is repeated to average exposing amounts at the pattern edge, whereby a pattern 46a of a resist having a smoothed edge surface can be formed as shown in FIG. 13B.

According to the embodiment, as in the case of the fourth embodiment, by smoothing the resist pattern, it can be formed a smooth wiring grove and contact hole, thereby forming a Cu wiring having small mean surface roughness therein.

Thus, in the wiring with a wiring width of 100 nm or less, the mean surface roughness of the wiring can be controlled within a range defined by the equation (11) with respect to the wiring width. Accordingly, it can be provided a semiconductor device capable of suppressing a reduction in electrical conductivity caused by surface roughness of a wiring to 2% or less, and its manufacturing method.

### Sixth Embodiment

A sixth embodiment of the present invention is directed to a semiconductor device which comprises a Cu wiring with small surface roughness formed in a wiring groove and a contact hole having smoothed surface formed in an interlevel insulator 22 patterned by using a smoothed hard mask pattern for etching the interlevel insulator 22, and its manufacturing method.

According to the embodiment, as shown in a sectional view of FIG. 14, on the interlevel insulator 22 to be formed the wiring groove and the contact hole therein, an etching stacked film 50 that comprises two or more films having different etching characteristics, e.g., an insulator 50a and an organic film 50b, is formed. For example, a coating type SiO₂ film such as polysiloxane can be used for the insulator 50a, and a coating type organic film such as a carbon film can be used for the organic film 50b. A resist pattern is formed on the etching stacked film 50.

When the etching stacked films 50a and 50b formed as above having different etching characteristics are sequentially etched while an etching gas is changed by layer, roughness of a patterned edge surface is smoothed as etching progresses layer by layer. That is, after etching the etching stacked film 50 of two layers shown in FIG. 14, an edge surface of the organic film 50b is smoother than that of a resist pattern 46, and an edge surface of the insulator 50a in the lower layer is much smoother than that of the organic film 50b. The example of the etching stacked film 50 of the two layers has been described. Effect of the smoothing is greater as the number of stacked layers is more and as a film thickness of each layer is thicker. Thus, a pattern of the insulator 50a formed just above the interlevel insulator 22 can be made smoother than that of the resist pattern 46. The interlevel insulator 22 is etched by using the smoothed insulator 50a as a hard mask, a wiring groove and a contact hole having smooth surfaces can be formed therein.

Accordingly, by smoothing the surfaces of the wiring groove and the contact hole, it can be formed a Cu wiring having small mean surface roughness.

Thus, in the wiring with a wiring width of 100 nm or less, the mean surface roughness of the wiring can be controlled within a range defined by the equation (11). Accordingly, it can be provided a semiconductor device capable of suppressing a reduction in electrical conductivity caused by surface roughness of a wiring to 2% or less, and its manufacturing method.

As described above, according to the present invention, it can be quantitatively determined a surface roughness Ra of a wiring corresponding to a wiring width w in a miniaturized semiconductor device and provided a semiconductor device which comprises a wiring having surface roughness Ra designed based on a result thereof and suitable for miniaturization.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
an insulator formed above a semiconductor substrate; and
a wiring formed in the insulator and having surface roughness capable of suppressing surface scattering of electrons and reduction in electrical conductivity thereof.

2. The semiconductor device according to claim 1, wherein the surface roughness Ra is represented by a following equation:
Ra≦1.06+0.26 w−0.97×10⁻⁴ w²
where w is a width of the wiring.

3. The semiconductor device according to claim 2, wherein the wiring is a copper wiring.

4. The semiconductor device according to claim 3, wherein the width of the wiring is 100 nm or less.

5. The semiconductor device according to claim 2, wherein the wiring has a width equal to or less than a mean free path of electrons in a wiring material.

6. The semiconductor device according to claim 2, wherein the width of the wiring is 100 nm or less.

7. The semiconductor device according to claim 2, wherein the wiring is formed on a smoothed barrier metal.

8. The semiconductor device according to claim 2, wherein the wiring is formed in at least one of a wiring groove and a contact hole whose surface is smoothed.

9. The semiconductor device according to claim 1, wherein the wiring is a copper wiring.

10. The semiconductor device according to claim 9, wherein the width of the wiring is 100 nm or less.

11. The semiconductor device according to claim 9, wherein the wiring is formed on an underlying layer having a smoothed surface.

12. The semiconductor device according to claim 1, wherein the width of the wiring is 100 nm or less.

13. The semiconductor device according to claim 1, wherein the wiring has a width equal to or less than a mean free path of electrons in a wiring material.

14. A method for manufacturing a semiconductor device, comprising:
forming an insulator above a semiconductor substrate;
forming at least one of a wiring groove and a contact hole in the insulator;
forming a barrier metal in at least one of the wiring groove and the contact hole;
smoothing a surface of at least one of the wiring groove, the contact hole and the barrier metal; and
forming a copper wiring on the barrier metal.

15. The method according to claim 14, wherein the surface roughness Ra is represented by a following equation:
Ra≦1.06+0.26 w−0.97×10⁻⁴ w²
where w is a width of the wiring.

16. The method according to claim 15, wherein the width of the wiring is 100 nm or less.

17. The method according to claim 15, wherein the smoothing the surface further comprises:
forming a mask pattern comprising a smooth edge surface, and
forming at least one of the wiring grove and the contact hole in the insulator by using the mask pattern.

18. The method according to claim 17, wherein the forming the mask pattern further comprises:
forming a resist pattern above the insulator; and
forming a smoothing film on the resist pattern.

19. The method according to claim 14, wherein the width of the wiring is 100 nm or less.

20. The method according to claim 14, wherein the wiring has a width equal to or less than a mean free path of electrons in a wiring material.
